(19) United States
(12) Patent Application Publication
(10) Pub. No.: US 2009/0304949 A1
(43) Pub. Date: Dec. 10, 2009

(54) SHORT PULSE ATMOSPHERIC PRESSURE GLOW DISCHARGE METHOD AND APPARATUS

(76) Inventors: Hindrik Willem De Vries, Tilburg (NL); Eugen Aldea, Eindhoven (NL); Mauritius Cornelius Maria Van De Sanden, Tilburg (NL)

Correspondence Address: FOLEY AND LARDNER LLP;SUITE 500, 3000 K STREET NW, WASHINGTON, DC, 20007, US

(21) Appl. No.: 12/278,905

(22) PCT Filed: Feb. 9, 2007
(86) PCT No.: PCT/NL2007/050052

§ 371 Date: Apr. 16, 2009

(30) Foreign Application Priority Data
Feb. 9, 2006 (EP) 06101450.2

(51) Int. Cl. C23C 16/513; H05H 1/24; C23C 16/00

(52) U.S. Cl. 427/569; 118/723 E

(57) ABSTRACT

Method and plasma generating apparatus for generating an atmospheric pressure glow discharge plasma in a treatment space (5) filled with a gas composition. Two electrodes (2, 3) are connected to a power supply (4) for providing electrical power during an on-time (tₒₙ). The power supply (4) is arranged to provide a periodic signal with an on-time (tₒₙ) which is shorter than a predetermined time period, the predetermined time period corresponding substantially to the time necessary for a dust coagulation center from the gas composition to become a cluster in the treatment space (5). This method and apparatus may be used for depositing a layer of material on a substrate (6) in the treatment space (5).

### FIELD OF THE INVENTION

The present invention relates to a method for providing an atmospheric pressure glow discharge plasma in a treatment space, in which the atmospheric pressure glow discharge plasma is generated by applying electrical power to at least two electrodes in the treatment space during an on-time, the treatment space being filled with a gas composition. In a further aspect, the present invention relates to a plasma generating apparatus for generating an atmospheric pressure glow discharge plasma in a treatment space filled with a gas composition, comprising at least two electrodes connected to a power supply for providing electrical power to the at least two electrodes during an on-time. In a further aspect of this invention, the apparatus is used for the deposition of a chemical substance.

### PRIOR ART

European patent application EP-A-1 340 838 discloses a method and device for atmospheric plasma processing, e.g. for etching a substrate or depositing a film on a substrate. Processed gas is exhausted from the vicinity of the treatment section to keep the surrounding of the substrate clear for plasma treatment. Treatment gas inlets and exhausts are used to maintain a specified atmosphere near the article to be treated. The plasma is generated using pulses to the electrodes for creating a stable glow discharge.

American patent publication US-A-2004/146660 discloses a surface coating method, in which e.g. an APG plasma is used to form a layer on a substrate from a gas mixture.

European patent application EP-A-1 029 702 discloses a surface treatment method for enhancing water absorption capability of a recording medium (inkjet paper), using a plasma treatment.

German patent application DE-A-44 38 533 discloses a method for generating a filamentary (corona) plasma at atmospheric pressure, using a pulsed power supply. This generated filamentary plasma is being used for surface treatment of various materials, such as modifying the adhesion properties of the surface. The conditions are such that only filamentary plasma is generated.

Japanese patent application abstract 07-074110 discloses a method for plasma chemical vapour deposition, in which at low pressure, a specific defined pulse form of the power applied to plasma generating electrodes is given, to enhance the quality of a film deposition process without producing dust.

In the article ‘Formation Kinetics and Control of Dust Particles in Capacitively-Coupled Reactive Plasmas’ by Y. Watanabe et al., Physica Scripta, Vol. T89, 29-32, 2001, a description is given of a study at reduced pressure of the influence of both the pulse on-time (tₒₙ) and pulse off-time (t_{off}) in capacitively coupled RF discharges (13.56 MHz) on the formation of dust particles. It was shown that an increase in t duration (tₒₙ>1 ms) increases the size and volume fraction of clusters slightly, though the most significant increase occurs above pulse on-time of 10 ms and longer. In this document, the terms clusters, particles, dust particles, dust and powder all have the same meaning.

Atmospheric pressure glow discharge plasma's are being used for surface treatment. In some cases, also a pulsed power supply is used, with a minimum on-time of the pulse of at least 2 ms. The atmospheric glow discharge plasma's with these pulse times have the disadvantage of dust formation, by which a smooth deposition of a chemical compound cannot be obtained. The prior art documents above do not address the problem of dust formation during plasma treatment.

### SUMMARY OF THE INVENTION

The present invention seeks to provide a method allowing the control of generation of specific species in an atmospheric pressure glow discharge plasma, to enable reactant processes in the plasma, e.g. for deposition of layers on a substrate, without the problem described above.

According to the present invention, a method according to the preamble defined above is provided, in which in the on-time is shorter than a predetermined time period, the predetermined time period corresponding substantially to the time necessary for a dust coagulation center from the gas composition to become a cluster in the treatment space. By controlling the on-time of the electrical power to form a plasma pulse, the forming of certain reactants may be controlled.

A problem in using plasma for deposition of layers of material is the formation of dust or powder of material, which results in a poor quality deposited layer (irregular, non-uniform, etc.). In the treatment space, in addition to the precursor of compounds to be deposited a gas composition at atmospheric pressure is present which may comprise oxygen or hydrogen and/or a noble gas, such as helium, neon or argon, and/or an inert gas, such as nitrogen. Applying the method according to the present invention will result in a big improvement of layer quality, much less powder formation and a better surface smoothness.

In a further embodiment, the predetermined time period is less than 0.5 ms, for example less than 0.3 ms. This will ensure that no or very little dust coagulation centers may be formed in the plasma. The on-time may be even as little as 0.2 ms or even 0.1 ms. Such short on-times may be accompanied by a change in the gas composition in order to assure that a layer of material of sufficient thickness may be deposited.

In a further embodiment dust prevention is achieved by controlling the absolute value of the charge density (product of current density and time) generated during the power on pulse. In one embodiment this value is smaller than 2 microCoulomb/cm², e.g. 1 microCoulomb/cm².

Further measures to enhance the layer deposition quality may include to apply no electrical power to the at least two electrodes during an off-time. This off-time will allow dust coagulation centers formed during the on-time (if any) to decay. In a further embodiment, the sum of on-time (tₒₙ) and off-time (t_{off}) substantially corresponds to a time of residence of the gas composition in the treatment space. This allows e.g. to accurately determine the necessary gas composition for providing a layer of a specified thickness.

In further embodiments, the duty cycle of on-time and off-time is less than 10%, e.g. in the range from 0.5-10%. This, in combination with the required short on-time to prevent formation of dust, is another way of defining the power supply signal for establishing the right APG plasma conditions. The electrical power may be applied using a generator, which provides a sequence of e.g. sine wave train signals as the periodic electrical power supply for the electrodes. The frequency range may be between 10 kHz and 30 MHz, e.g. between 100 kHz and 450 kHz.

In a further embodiment, the gas composition comprises a precursor of a chemical compound or chemical element and an oxygen or hydrogen comprising gas. The precursor is e.g. used in a concentration from 10 to 500 ppm. The gas composition may further comprise a noble gas, such as helium, neon or argon, and/or an inert gas, such as nitrogen.

In a further aspect, the present invention relates to a plasma generating apparatus according to the preamble as defined above, in which the power supply is arranged to provide a periodic signal with an on-time which is shorter than a predetermined time period, the predetermined time period corresponding substantially to the time necessary for a dust coagulation centers from the gas composition to become a cluster in the treatment space. In a further embodiment, the predetermined time period is less than 0.5 ms, for example less than 0.3 ms. The power supply may be arranged to apply no electrical power to the at least two electrodes during an off-time, and in a further embodiment, the sum of on-time (tₒₙ) and off-time (t_{off}) substantially corresponds to a time of residence of the gas composition in the treatment space.

The power supply may be arranged to generate pulse sequences such that the absolute value of the charge density (product of current density and time) generated during the power on pulse is smaller than 2 microCoulomb/cm², e.g. 1 microCoulomb/cm².

The power supply may be arranged for providing the periodic signal with a duty cycle of on-time and off-time of less than 10%. The duty cycle may be adjusted in steps of 1%. The power supply may be arranged to provide a frequency range between 10 kHz and 30 MHz, e.g. between 100 kHz and 450 kHz. The present plasma generating apparatus allows to execute the method embodiments as described above, with similar advantages.

As mentioned above in relation to the method embodiments, the present plasma generating apparatus may be used advantageously for depositing layers of material on a substrate. For this, the plasma generating apparatus may be arranged to receive a gas composition comprising a precursor of a chemical compound or chemical element to be deposited and an oxygen or hydrogen comprising gas in the treatment space. The precursor is e.g. used in a concentration from 10 to 500 ppm. The gas composition may further comprise a noble gas, such as helium, neon or argon, and/or an inert gas, such as nitrogen.

In an even further aspect, the present invention relates to the use of a plasma generating apparatus according to any one embodiment of the present invention for depositing a layer of material on a substrate in the treatment chamber.

### SHORT DESCRIPTION OF DRAWINGS

The present invention will be discussed in more detail below, using a number of exemplary embodiments, with reference to the attached drawings, in which

FIG. 1 shows a schematic view of a plasma generation apparatus in which the present invention may be embodied;

FIG. 2 shows a plot of a periodic signal generated by the power supply to feed the electrodes of the plasma generation apparatus of FIG. 1;

FIG. 3 shows an electron microscope pictures of a surface deposited with an apparatus and method according to this invention;

FIG. 4 shows an electron microscope picture of a surface deposit obtained using a prior art method.

### DETAILED DESCRIPTION OF EXEMPLARY EMBODIMENTS

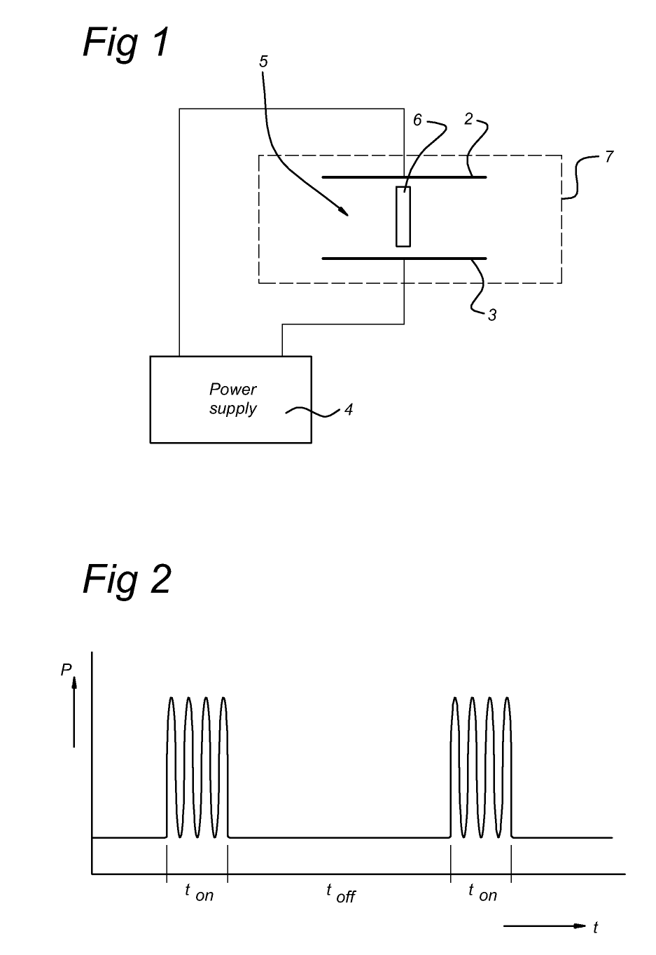

FIG. 1 shows a schematic view of a plasma apparatus in which the present invention may be applied. A treatment space 5, which may be a treatment chamber within an enclosure 7, or a treatment space 5 with an open structure, comprises two electrodes 2, 3. In general the electrodes 2, 3 are provided with a dielectric barrier in order to be able to generate and sustain a glow discharge at atmospheric pressure in the treatment space. Alternatively, a plurality of electrodes 2, 3 is provided. The electrodes 2, 3 are connected to a power supply 4, which is arranged to provide electrical power to the electrodes for generating the glow discharge plasma. The power supply 4 may be arranged to provide a periodic electrical signal with an on-time t and an off-time t_{off}, the sum of the on-time and off-time being the period of the periodic electrical signal. The power supply can be a power supply providing a wide range of frequencies, For example it can provide a low frequency (f=10-450 kHz) electrical signal during the on-time. It can also provide a high frequency electrical signal for example f=450 kHz-30 MHz. The on-time may vary, but for the present invention, the on-time may range from very short, e.g. 2 μs, to short, e.g. 500 ms. During the on-time, this effectively results in a pulse train having a series of sine wave periods at the operating frequency, with a total duration of the on-time (e.g. 10 to 30 periods of a sine wave) of 0.1 to 0.3 ms. This is schematically shown in the graph of FIG. 2.

The arrangement of FIG. 1 may be used for deposition of an inorganic material to a substrate 6. In such a deposition process a gas composition including a precursor of the material to be deposited is brought into contact with a pulsed atmospheric plasma. Upon contact with the plasma the precursor reacts or dissociates in order to form compounds in treatment space 5 which either will deposit on the substrate 6 or remain in the gas phase. By using very short on-times of the APG plasma, further reaction of the compounds is effectively prevented, allowing to control the chemical reactions in the treatment space 5 more efficiently.

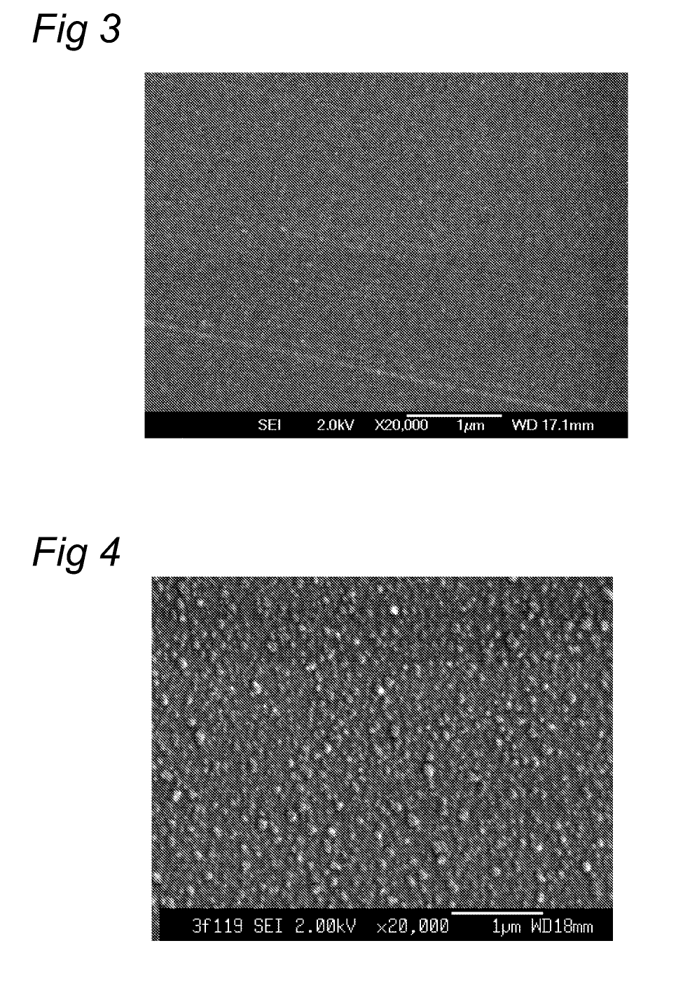

The precursor will decompose as soon as it enters a plasma environment. How the precursor decomposes precisely (which further reaction can occur in the plasma with the initial breakdown components) is not clear. Because there is a very dense concentration of reactive species in the plasma, easy reaction can occur amongst these species and between these species and for example oxygen. In case a number of these species react with each other one can get a so called coagulation center. According to the literature these are smaller than about 10 nm in size and probably each center might have a different composition. Such small centers should be formed as little as possible, as combination of these centers will result at the end in dust, powder, particles, or clusters to name a few terms. The SEM pictures of one of our dusty surfaces (See FIGS. 3 and 4) indicate that the dust particles might be as small as 10 nm (see value of coagulation centre) to more than 150 nm.

In an exemplary embodiment, below the use of the apparatus of FIG. 1 using the timing of the power supply 4 according to FIG. 2, is explained for depositing layers of a chemical compound or chemical element on a substrate 6 in the treatment space 5. In the treatment space 5, a combination of gasses is introduced, e.g. comprising a noble gas like helium, neon or argon, an inert gas like for example nitrogen, a precursor of a substance to be precipitated and a reactive gas like for example hydrogen or oxygen. Under the influence of the electrical pulses from the power supply, a pulsed atmospheric pressure glow discharge plasma is formed in the treatment space 5. The power on-time of the APG plasma is short enough not to cause additional secondary reaction of the compounds formed after dissociation of the precursor, thus allowing a much more effective deposition process. So far a satisfactory explanation of this phenomenon could not be provided

At atmospheric pressure the use of pulsing is known to the skilled person as a method to generate a larger density of filaments in a corona dielectric barrier discharge plasma. The plasma bursts in such corona like plasma consist of a train of sine waves having for example a frequency of 15-50 kHz. In such a case the interval between the plasma bursts is in the range of 20 μs to 100 ms.

In the present invention, the apparatus as shown in FIG. 1 is not used to generate filamentary discharges but for generating glow discharges.

In low pressure plasma applications, it is known to apply plasma pulsing in order to influence the plasma chemistry. The chemical reactivity of plasma is due to the dissociation of reactive molecules. In several cases it is necessary to limit the dissociation of molecules by plasma in order to avoid excessive degradation of the molecules or the formation of macro polymers in plasmas or dust formation. Pulsing the power applied to the plasma is a standard way to diminish the plasma reactivity by decreasing the average energy transferred to the plasma per unit of time. Pulsing has the disadvantage of a slower treatment of a surface so the low duty cycle option pulsing is an option only for a limited range of gas mixtures when the density of dissociated molecules remains large enough during plasma off-time. Typically pulses of 1-20 ms with duty cycles of 10-50% are used.

For atmospheric pressure glow plasma's dust formation is a serious concern in plasmas used for high quality applications (microelectronics, permeation barrier, optical applications). For such applications the dust formation can compromise the quality of the coating. At atmospheric pressure dust formation is a common fact, due to the typical large power density of the plasma and large concentrations of reactive molecules formed after dissociation of the precursor molecule. For this reason the industrial use of atmospheric plasmas for coating applications is presently limited to low-end applications such as increasing adhesion. In low pressure applications for example, no reports of dust formation in for example Ar/O₂/HMDSO (hexamethyldisiloxane) plasmas are known, although at high pressure this plasma variety generates extremely dusty coatings after only a few seconds of exposure to the plasma.

With respect to the mechanism of dust formation in plasma's at atmospheric pressure, it is assumed that the dust coagulation centers are negative and positive ions. At low pressure the ions can not survive more than few milliseconds after the plasma is extinguished. Pulsing the plasma with an off-time of a few milliseconds is enough to interrupt the growth of dust particles and to limit thus the dust formation. At low pressure the dust particles grow relatively slow (˜10 s to become of significant size), so that the power on-time can be relatively long (in the order of hundreds of ms).

Therefore, in general, the standard method for suppression of dust formation is based on the fast decay of dust coagulation centers during the power off-time of the plasma. This can be regarded as a “natural death” of the dust coagulation centers during the plasma off-time. Moreover, because only a short period of power off-time is needed and a relatively long pulse duration, the duty cycle of these pulsing examples is large, typically in the range of 50-98%.

According to the present invention, ultra short pulses are applied to prevent powder or dust formation in the gas phase at atmospheric pressure in the plasma, hence substantially improving the quality of the deposit on the substrate 6.

To the contrary of low pressure case at atmospheric pressure the decay of dust coagulation centers is much slower than at low pressure, i.e. in the order of at least tens of milliseconds. In principle, by having the power supply 4 to provide larger power off-times of tens of ms, it is expected that dust formation is suppressed.

During our experimentation, it was however surprisingly found that for atmospheric plasma's, using various precursors in a gas mixture as for example Ar/O2 it was not possible to suppress the dust formation sufficiently, even with 100 ms between pulses (5 ms plasma on-time). This indicates that the chemistry responsible for the dust formation is still intense during the power off-time.

In the present invention precursors can be can be selected from (but are not limited to): W(CO)6, Ni(CO)4, Mo(CO)6, Co2(CO)8, Rh4(CO)12, Re2(CO)10, Cr(CO)6, or Ru3(CO)12, Tantalum Ethoxide (Ta(OC₂H₅)₅), Tetra Dimethyl amino Titanium (or TDMAT) SiH₄CH₄, B₂H₆ or BCl₃, WF₆, TiCl₄, GeH4, Ge2H6Si2H6 (GeH3)3SiH (GeH3)2SiH2, hexamethyldisiloxane (HMDSO), tetramethyldisiloxane (TMDSO), and 1,1,3,3,5,5-hexamethyltrisiloxane., hexamethylcyclotetrasiloxane, octamethylcyclotetrasiloxane, decamethylcyclopentanesiloxane, tetraethoxysilane (TEOS), methyltrimethoxysilane, methyltriethoxysilane, dimethyldimethoxysilane, dimethyldiethoxysilane, trimethylethoxysilane, ethyltrimethoxysilane, ethyltriethoxysilane, n-propyltrimethoxysilane, n-propyltriethoxysilane, n-butyltrimethoxysilane, i-butyltrimethoxysilane, n-hexyltrimethoxysilane, phenyltrimethoxysilane, vinyltrimethoxysilane, vinyltriethoxysilane. aminomethyltrimethylsilane, dimethyldimethylaminosilane, dimethylaminotrimethylsilane, allylaminotrimethylsilane, diethylaminodimethylsilane, 1-trimethylsilylpyrrole, 1-trimethylsilylpyrrolidine, isopropylaminomethyltrimethylsilane, diethylaminotrimethylsilane, anilinotrimethylsilane, 2-piperidinoethyltrimethylsilane, 3-butylaminopropyltrimethylsilane, 3-piperidinopropyltrimethylsilane, bis(dimethylamino)methylsilane, 1-trimethylsilylimidazole, bis(ethylamino)dimethylsilane, bis(butylamino)dimethylsilane, 2-aminoethylaminomethyldimethylphenylsilane, 3-(4-methylpiperazinopropyl)trimethylsilane, dimethylphenylpiperazinomethylsilane, butyldimethyl-3-piperazinopropylsilane, dianilino dimethylsilane, bis(dimethylamino)diphenylsilane. 1,1,3,3-tetramethyldisilazane, 1,3-bis(chloromethyl)-1,1,3,3-tetramethyldisilazane, hexamethyldisilazane, 1,3-divinyl-1,1,3,3-tetramethyldisilazane, dibutyltin diacetate, dimethyl aluminium, aluminum isopropoxide, tris(2,4-pentadionato)aluminuminclude dibutyldiethoxytin, butyltin tris(2,4-pentanedionato), tetraethoxytin, methyltriethoxytin, diethyldiethoxytin, triisopropylethoxytin, ethylethoxytin, methylmethoxytin, isopropylisopropoxytin, tetrabutoxytin, diethoxytin, dimethoxytin, diisopropoxytin, dibutoxytin, dibutyryloxytin, diethyltin, tetrabutyltin, tin bis(2,4-pentanedionato), ethyltin acetoacetonato, ethoxytin (2,4-pentanedionato), dimethyltin (2,4-pentanedionato), diacetomethylacetatotin, diacetoxytin, dibutoxydiacetoxytin, diacetoxytin diacetoacetonato, tin hydride, tin dichloride tin tetrachloridetriethoxytitanium, trimethoxytitanium, triisopropoxytitanium, tributoxytitanium, tetraethoxytitanium, tetraisopropoxytitanium, methyldimethoxytitanium, ethyltriethoxytitanium, methyltripropoxytitanium, triethyltitanium, triisopropyltitanium, tributyltitanium, tetraethyltitanium, tetraisopropyltitanium, tetrabutyltitanium, tetradimethylaminotitanium, dimethyltitanium di(2,4-pentanedionato), ethyltitanium tri(2,4-pentanedionato), titanium tris(2,4-pentanedionato), titanium tris(acetomethylacetato), triacetoxytitanium, dipropoxypropionyloxytitanium, dibutyryloxytitanium, monotitanium hydride, dititanium hydride, trichlorotitanium, tetrachlorotitanium. tetraethylsilane, tetramethylsilane, tetraisopropylsilane, tetrabutylsilane, tetraisopropoxysilane, diethylsilane di(2,4-pentanedionato), methyltriethoxysilane, ethyltriethoxysilane, silane tetrahydride, disilane hexahydride, tetrachlorosilane, methyltrichlorosilane, diethyldichlorosilane, isopropoxyaluminum, tris(2,4-pentanedionato)nickel, bis(2,4-pentanedionato)manganese, isopropoxyboron, tri-n-butoxyantimony, tri-n-butylantimony, di-n-butylbis(2,4-pentanedionato)tin, di-n-butyldiacetoxytin, di-t-butyldiacetoxytin, tetraisopropoxytin, dimethyl zinc, zinc di(2,4-pentanedionate), and combinations thereof. Furthermore precursors can be used as for example described in EP-A-1351321 or EP-A-1371752. Generally the precursors are used in a concentration of 10-500 ppm e.g. around 50 ppm of the total gas composition.

Due to large density of molecules and radicals the dust formation can occur at a high speed even during the power off-time in reactions between radicals, ions and precursor gas. Thus the standard method based on the decay of dust coagulation centers during the power off-time does not work at atmospheric pressure because their decay is slow and the chemistry in afterglow much more intense than for low pressure plasmas.

The proposed method according to embodiments of the present invention is not based on the “natural dead” (decay) of dust coagulation centers but on minimizing their density in the plasma, i.e. from the stage of power on-time. To the contrary of prior art methods, which involve a manipulation of dust formation based on the decay of coagulation centers via adjustment of power off-time, this is rather a method based on preventing the formation of the coagulation centers from the beginning by adjusting power on-time.

According to the present invention, the power on-time is chosen in such a way that the formation of dust coagulation centers will be minimized, probably by minimizing secondary reactions like electron attachment, ozone formation and the like. In order to maintain an efficient deposition the pulse is chosen to be long enough to sustain a significant deposition rate.

Due to these limitations the width of the pulse as provided by the power supply 4 to the electrodes 2, 3, is precisely defined for each type of plasma and is depending on the power value. Typically, power on-times of a fraction of millisecond are used (t in the range of 0.1-0.5 ms, e.g. 0.1-0.3 ms). As a rough estimation the electron density is proportional with the power density (averaged over half period). According to our experimental results the product between pulse duration and the plasma power density should be smaller than 2 mJ/cm² or more preferable the absolute value of the charge density (product of current density and time) generated during the power on pulse is e.g. smaller than 2 microCoulomb/cm², for example 1 microCoulomb/cm².

The frequency provided by the power supply can be chosen freely, taking into account above mentioned limitations. The frequency can have a value for example of between 10 kHz and 30 MHz. Also good results were obtained in the low frequencies range of 100-450 kHz.

Moreover, in further embodiments, the interval between pulses (off-time t_{off}) and the gas composition is adjusted in such a way that the formed dust coagulation centers are suppressed at the end of the interval between pulses. For example, if the amount of coagulation centers is not suppressed during the power off-time, formation clusters will occur extremely fast during the power on-time tₒₙ. In such a case extremely short power on-time tₒₙ must be used.

For minimizing the density of dust coagulation centres the use of an interval between pulses (t_{off}) in the order of the time of residence of the gas in the treatment space 5 of a reactor can also advantageously be used in the present invention. In this case the time between pulses should be comparable to the residence time of the gas in the discharge space. In the case of argon/oxygen/HMDSO for example we suspect the existence of coagulation with a longer lifetime which need to be flushed before the start of the next pulse. A residence time which is shorter than the cycle time (sum of pulse on-time and pulse off-time) is on the safe side, the residence time should in any case be chosen such, that there is no accumulation of dust coagulation centers.

The proposed pulsed plasma method of the present invention, is based on the suppression of formation of the dust coagulation centers from the initial phase during the power on-time tₒₙ. Furthermore, it is based on the decay of the dust coagulation centers by adjusting the power off-time t_{off} and by adjusting the gas composition. The total amount of coagulation centers seem to be determined by the amount of the precursor of the chemical compound or chemical element to be deposited in the plasma gas composition, and the gas mixture used, for example the percentage of oxygen and of course the gas flow as discussed above. In case the precursor amount in the gas mixture is reduced and/or the amount of reactive gas like hydrogen or oxygen, the amount of coagulation centers in the plasma gas will also be reduced. Reducing the precursor amount in the gas composition will off course influence the efficiency of the deposition process. Best results are obtained in general with a precursor concentration from 10 to 500 ppm of the gas phase and for example an oxygen concentration of more than 0.1% of the gas phase.

An efficient way of controlling the generation of dust coagulation centers may be accomplished by having the power supply 4 operate at low duty cycles (0.5-10%) and with short power on-times in the order of 0.1-0.3 ms. The power on-time tₒₙ and power off-time t_{off} are precisely adjusted in order to maintain an efficient deposition process but within the limits imposed by the above mentioned conditions. In general terms, the sum of on-time (tₒₙ) and off-time (t_{off}) or cycle time, substantially corresponds to the time of residence of the gas compositions in the treatment space.

Until now the dust free deposition of chemical compounds using atmospheric pressure glow discharge plasma's could not be achieved, because of the absence of power supplies which were capable of providing very short pulses. According to the present invention power supply 4 is used having the possibility to generate ultra short pulse trains from 50 μs up to more than 500 ms. Using this power supply pulse trains may in fact be formed of a series of sine waves having a total duration time (pulse on-time) of 100-300 microseconds. In total the pulse train contains typically 10 to 30 periods of such sine waves.

A first exemplary reference test was performed using an excitation frequency of 130 kHz and a 4 ms pulse on-time with a 10% duty cycle (i.e. a 36 ms pulse off-time). Typical dimension of the electrode are a gap distance of 1 mm and a “working length” (width) of 4 cm. The gas flow yields a typical gas flow speed of about 1 m/s. The gas composition in the treatment space 5 comprised a mixture of Argon, 5% 02, and HMDSO. The result was a layer deposition with clear dust formation on the surface 6, as examined in a 20,000 magnification image of the surface 6, as shown in FIG. 4. Longer pulse on-times showed even much stronger powder formation.

A second exemplary test according to an embodiment of the present invention was performed using an excitation frequency of 130 kHz and pulse on-time of 0.2 ms with a 0.5% duty cycle. The electrode gap and gas flow was kept the same as in the first exemplary reference test. The gas composition in the treatment space 5 again comprised a mixture of Argon, 5% O₂, and HMDSO. The result this time was a very uniform layer deposition on the surface 6, again examined in a 20,000 magnification image, as shown in FIG. 3. Note that in this case part of the sample with some dust particles had to be used to be able to focus on the surface 6.

In the tables I-IV below some results are given with respect to the quality of the obtained coatings using various conditions and various precursors.

In order to generate such short pulses, an external oscillator was build using a standard PC equipped with a National Instruments interface card PCI-MIO-16E-4. The desired pulse trains are programmed and send as an analog signal to the amplifier (in this case type RFPP-LF 10a).

TABLE I
Gas injection: argon 10 slm oxygen 0.5 slm;
Precursor injection: HMDSO 300 mg/hr

| | Pulse on time | | Smoothness/ |
|---|---|---|---|
| Frequency | [microseconds] | Duty cycle [%] | no dust |
| 50 kHz | 200 | 0.5 | ◯ |
| | 200 | 10 | Δ |
| | 200 | 20 | X |
| | 500 | 0.5 | ◯ |
| | 500 | 10 | Δ |
| | 500 | 20 | X |
| | 2000 | 0.5 | X |
| 130 kHz | 100 | 0.5 | ◯ |
| | 100 | 10 | Δ |
| | 100 | 20 | X |
| | 200 | 0.5 | ◯ |
| | 200 | 10 | Δ |
| | 200 | 20 | X |
| | 4000 | 0.5 | X |
| | 4000 | 10 | X |
| 450 kHz | 50 | 0.5 | ◯ |
| | 50 | 10 | Δ |
| | 200 | 0.5 | ◯ |
| | 200 | 10 | Δ |
| | 200 | 20 | X |
| | 2000 | 0.5 | X |
| 13.65 MHz | 1 | 0.5 | ◯ |
| | 1 | 10 | Δ |
| | 50 | 0.5 | ◯ |
| | 50 | 10 | Δ |
| | 1000 | 0.5 | X |

◯: No dust
Δ: Some dust particles visible
X: Dusty appearance

TABLE II
Gas injection: argon 10 slm oxygen 0.2 slm;
Precursor injection: TEOS 600 mg/hr

| | Pulse on time | | Smoothness/ |
|---|---|---|---|
| Frequency | [microseconds] | Duty cycle [%] | no dust |
| 50 kHz | 200 | 0.5 | ◯ |
| | 200 | 10 | Δ |
| | 200 | 20 | X |
| | 500 | 0.5 | ◯ |
| | 500 | 10 | Δ |
| | 500 | 20 | X |
| | 2000 | 0.5 | X |
| 130 kHz | 100 | 0.5 | ◯ |
| | 100 | 10 | Δ |
| | 100 | 20 | X |
| | 200 | 0.5 | ◯ |
| | 200 | 10 | Δ |
| | 200 | 20 | X |
| | 4000 | 0.5 | X |
| | 4000 | 10 | X |
| 450 kHz | 50 | 0.5 | ◯ |
| | 50 | 10 | Δ |
| | 200 | 0.5 | ◯ |
| | 200 | 10 | Δ |
| | 200 | 20 | X |
| | 2000 | 0.5 | X |
| | 2000 | 10 | X |
| 13.65 MHz | 5 | 0.5 | ◯ |
| | 5 | 5 | ◯ |
| | 50 | 0.5 | ◯ |
| | 50 | 10 | Δ |
| | 50 | 20 | X |
| | 1000 | 0.5 | X |
| | 1000 | 10 | X |

◯: No dust
Δ: Some dust particles visible
X: Dusty appearance

TABLE III
Gas injection: argon 10 slm oxygen 0.1 slm;
Precursor injection: TPOT 100 mg/hr

| | Pulse on time | | Smoothness/ |
|---|---|---|---|
| Frequency | [microseconds] | Duty cycle [%] | no dust |
| 50 kHz | 240 | 0.5 | ◯ |
| | 240 | 10 | Δ |
| | 500 | 0.5 | ◯ |
| | 500 | 10 | Δ |
| | 500 | 20 | X |
| | 2000 | 0.5 | X |
| 130 kHz | 100 | 0.5 | ◯ |
| | 100 | 10 | Δ |
| | 100 | 20 | X |
| | 200 | 0.5 | ◯ |
| | 200 | 10 | Δ |
| | 200 | 20 | X |
| | 4000 | 0.5 | X |
| | 4000 | 10 | X |
| 450 kHz | 50 | 0.5 | ◯ |
| | 50 | 10 | Δ |
| | 200 | 0.5 | ◯ |
| | 200 | 10 | Δ |
| | 200 | 20 | X |
| | 2000 | 0.5 | X |
| 13.65 MHz | 1 | 0.5 | ◯ |
| | 1 | 5 | ◯ |
| | 50 | 0.5 | ◯ |
| | 50 | 10 | Δ |
| | 1000 | 0.5 | X |
| | 1000 | 10 | X |

◯: No dust
Δ: Some dust particles visible
X: Dusty appearance

TABLE IV
Gas injection: argon 10 slm oxygen 0.2 slm;
Precursor injection: DiMethylZinc 50 mg/hr

| | Pulse on time | | Smoothness/ |
|---|---|---|---|
| Frequency | [microseconds] | Duty cycle [%] | no dust |
| 50 kHz | 200 | 0.5 | ◯ |
| | 200 | 10 | Δ |
| | 200 | 20 | X |
| | 500 | 0.5 | ◯ |
| | 500 | 10 | Δ |
| | 500 | 20 | X |
| | 2000 | 0.5 | X |
| 130 kHz | 120 | 0.5 | ◯ |
| | 120 | 10 | Δ |
| | 120 | 20 | X |
| | 200 | 0.5 | ◯ |
| | 200 | 10 | Δ |
| | 200 | 20 | X |
| | 4000 | 0.5 | X |
| | 4000 | 10 | X |
| 450 kHz | 40 | 0.5 | ◯ |
| | 40 | 10 | Δ |
| | 200 | 0.5 | ◯ |
| | 200 | 10 | Δ |
| | 200 | 20 | X |
| | 2000 | 0.5 | X |
| 13.65 MHz | 5 | 0.5 | ◯ |
| | 5 | 10 | Δ |
| | 50 | 0.5 | ◯ |
| | 50 | 10 | Δ |
| | 50 | 30 | X |
| | 1000 | 0.5 | X |

◯: No dust
Δ: Some dust particles visible
X: Dusty appearance

1. A method for providing an atmospheric pressure glow discharge plasma in a treatment space, comprising applying electrical power to at least two electrodes in the treatment space filled with a gas composition during an on-time (tₒₙ) that is shorter than a predetermined time period, the predetermined time period corresponding substantially to the time necessary for dust coagulation centers from the gas composition to become a cluster in the treatment space.

2. The method according to claim 1, in which the predetermined time period is less than 0.5 ms.

3. The method according to claim 1, in which the electrical power applied has a charge density absolute value is smaller than 2 microCoulomb/cm².

4. The method according to claim 1, in which no electrical power is applied to the at least two electrodes during an off-time (t_{off}).

5. The method according to claim 4, in which the sum of on-time (tₒₙ) and off-time (t_{off}) substantially corresponds to a time of residence of the gas composition in the treatment space.

6. The method according to claim 4, in which the duty cycle of on-time (tₒₙ) and off-time (t_{off}) is less than 10%.

7. The method according to claim 1, in which the electrical power is applied with a frequency range between 10 kHz and 30 MHz.

8. The method according to claim 7, in which the electrical power is applied with a frequency range between 100 kHz and 450 kHz.

9. The method N according to claim 1, in which the gas composition comprises a precursor of a chemical compound or chemical element and an oxygen or hydrogen comprising gas.

10. The method according to claim 9, in which the precursor is used in a concentration from 10 to 500 ppm.

11. The method according to claim 9, in which the gas composition further comprises a noble gas.

12. The method according to claim 9, in which the gas composition further comprises an inert gas.

13. A plasma generating apparatus for generating an atmospheric pressure glow discharge plasma in a treatment space filled with a gas composition, the apparatus comprising at least two electrodes connected to a power supply for providing electrical power to the at least two electrodes during an on-time (tₒₙ), in which the power supply provides a periodic signal with an on-time (tₒₙ) which is shorter than a predetermined time period, the predetermined time period corresponding substantially to the time necessary for forming dust coagulation centers from the gas composition to become a cluster in the treatment space.

14. The plasma generating apparatus according to claim 13, in which the predetermined time period is less than 0.5 ms.

15. The plasma generating apparatus according to claim 13, in which the power supply applies no electrical power to the at least two electrodes during an off-time (t_{off}).

16. The plasma generating apparatus according to claim 15, in which sum of on-time (tₒₙ) and off-time (t_{off}) substantially corresponds to a time of residence of the gas composition in the treatment space.

17. The plasma generating apparatus according to claim 15, in which the power supply is arranged for providing the periodic signal with a duty cycle of on-time (tₒₙ) and off-time (t_{off}) of less than 10%.

18. The plasma generating apparatus according to claim 13, in which the power supply is arranged to provide a frequency range between 10 kHz and 30 MHz.

19. The plasma generating apparatus according to claim 18, in which the frequency range is between 100 kHz and 450 kHz.

20. The plasma generating apparatus according to claim 13, in which the power supply is arranged to provide a charge density during the power on pulse having an absolute value smaller than 2 microCoulomb/cm².

21. The plasma generating apparatus according to claim 13, in which the plasma generating apparatus is arranged to receive a gas composition comprising a precursor of a chemical compound or chemical element and an oxygen or hydrogen comprising gas in the treatment space.

22. The plasma generating apparatus according to claim 21, in which the precursor is used in a concentration from 10 to 500 ppm.

23. The plasma generating apparatus according to claim 21, in which the gas composition further comprises a noble gas, such as helium, neon or.

24. The plasma generating apparatus according to claim 21, 22 or 23, in which the gas composition further comprises an inert gas.

25. (canceled)

26. The method according to claim 2, in which the predetermined time period is less than 0.3.

27. The method according to claim 3, in which the electrical power applied has a charge density absolute value of 1 microCoulomb/cm².

28. The method according to claim 11, in which the noble gas comprises helium, neon, or argon.

29. The method according to claim 12, in which the inert gas is nitrogen.

30. A method of depositing a layer of material on a substrate comprising:
(a) providing an atmospheric pressure glow discharge plasma in a treatment space by applying electrical power to at least two electrodes in the treatment space filled with a gas composition during an on-time (tₒₙ) that is shorter than a predetermined time period, the predetermined time period corresponding substantially to the time necessary for dust coagulation centers from the gas composition to become a cluster in the treatment space; and
(b) depositing atmospheric pressure glow discharge plasma on the substrate.
